(19) United States
(12) Patent Application Publication
(10) Pub. No.: US 2024/0372327 A1
(43) Pub. Date: Nov. 7, 2024

(54) VCSEL AND FABRICATION METHOD THEREOF

(71) Applicant: SHENZHEN RAYSEES AI TECHNOLOGY CO., LTD., Shenzhen (CN)

(72) Inventors: Geng Chen, Hefei (CN); Siva Kumar Lanka, Reno, NV (US); Yongxiang He, Sunnyvale, CA (US); Yang Wang, Hefei (CN)

(73) Assignee: SHENZHEN RAYSEES AI TECHNOLOGY CO., LTD., Shenzhen (CN)

(21) Appl. No.: 18/037,238

(22) PCT Filed: Mar. 16, 2023
(86) PCT No.: PCT/CN2023/081867

§ 371 Date: May 16, 2023

(51) Int. Cl. H01S 5/183; H01S 5/34

(52) U.S. Cl. CPC H01S 5/18311; H01S 5/18361; H01S 5/34

(57) ABSTRACT

A VCSEL includes a substrate, a first reflector region, a second reflector region, an active region, and an oxide aperture. The second reflector region contains mirror pairs. The mirror pair has a first layer and a second layer. An edge of the first layer and an edge of the second layer are aligned along a direction approximately perpendicular to the substrate.

### FIELD OF INVENTION

This invention generally relates to Vertical Cavity Surface Emitting Lasers (VCSELs) and to the fabrication method of VCSELs.

### BACKGROUND OF THE INVENTION

VCSELs have a vertical cavity and epitaxially grown layers that form distributed Bragg reflectors (DBRs) as mirrors, while edge-emitting semiconductor lasers have a horizontal cavity and cleaved facets as mirrors. The advantages of VCSELs over edge-emitting semiconductor lasers include compact size, small circular beam spot, wavelength stability, spectral width, fast rise time, ease of fabricating two-dimensional (2-D) VCSEL arrays, manufacturability, etc.

Some VCSELs have an oxide layer that forms an oxide aperture for electrical and optical confinement during an operation. When the oxide aperture is made, some layers of the DBR are oxidized at the edge of a mesa. The oxidation in the DBR region can cause high mechanical stress and create certain structural weakness, which leads to poor reliability and even results in catastrophic premature random failures of VCSELs.

### SUMMARY OF THE INVENTION

The present invention discloses VCSELs and methods to make VCSELs. In one aspect, a VCSEL includes a substrate, a first reflector region over the substrate, a second reflector region over the first reflector region, an active region between the first reflector region and second reflector region, and an oxide aperture proximate to the active region. The second reflector region includes multiple mirror pairs. The mirror pair includes a first layer and a second layer, and an edge of the first layer and an edge of the second layer are aligned along a direction approximately perpendicular to the substrate.

In another aspect, a method for fabricating a VCSEL includes growing a first reflector region over a substrate, growing an active region over the first reflector region, growing a second reflector region over the active region, and removing a portion of the second reflector region by etch. The second reflector region includes a mirror pair containing a first layer and a second layer. Sides of the first layer and the second layer are exposed after the portion is removed. The method further includes forming a dielectric layer over the exposed sides of the first and second layers, and performing an oxidation process to form an oxide aperture for the VCSEL.

In another aspect, a VCSEL includes a substrate, a first reflector region over the substrate, a second reflector region over the first reflector region and surrounded by a dielectric region, an active region between the first reflector region and second reflector region, and an oxide aperture proximate to the active region. The second reflector region includes multiple mirror pairs. The mirror pair contains a first layer and a second layer. An edge of the first layer and an edge of the second layer contact the dielectric region.

### BRIEF DESCRIPTION OF THE DRAWINGS

The subject matter, which is regarded as the invention, is particularly pointed out and distinctly claimed in the claims at the conclusion of the specification. The foregoing and other features and also the advantages of the invention will be apparent from the following detailed description taken in conjunction with the accompanying drawings.

FIG. 1 is a cross-sectional view of a prior art VCSEL.

FIG. 2 schematically illustrates a cross-sectional view of a VCSEL at a certain stage during a fabrication process, according to embodiments of the present invention.

FIG. 3 schematically illustrates a cross-sectional view of the VCSEL shown in FIG. 4 after a mesa is made, according to embodiments of the present invention.

FIGS. 4, 5, and 6 schematically illustrate cross-sectional views of the VCSEL shown in FIG. 3 at certain stages of the fabrication process, according to embodiments of the present invention.

FIG. 7 schematically illustrates a cross-sectional view of the VCSEL shown in FIG. 6 after an oxidation process is performed, according to embodiments of the present invention.

FIG. 8 schematically illustrates a cross-sectional view of the VCSEL shown in FIG. 7 at a certain stage of the fabrication process, according to embodiments of the present invention.

FIG. 9 schematically illustrates a cross-sectional view of another VCSEL at a certain stage of a fabrication process, according to embodiments of the present invention.

FIG. 10 is a flow chart illustrating a schematic fabrication process, according to embodiments of the present invention.

### DETAILED DESCRIPTION

Detailed description of the present invention is provided below along with figures and embodiments, which further clarifies the objectives, technical solutions, and advantages of the present invention. Wherever possible, the same reference numbers are used throughout the drawings to refer to the same or like parts. It is noted that schematic embodiments discussed herein are merely for illustrating the invention. The present invention is not limited to the embodiments disclosed.

FIG. 1 shows a prior art Vertical Cavity Surface Emitting Laser (VCSEL) 100 in a cross-sectional view in an X-Z plane. VCSEL 100 represents a top-emitting VCSEL structure which emits an output beam through the top surface when charged with an electrical current. VCSEL 100 includes an active region 101, a top reflector region 102, a bottom reflector region 103, and a substrate 104. Active region 101 contains a multiple-quantum-well (MQW) configuration. Top reflector region 102 contains a p-type distributed Bragg reflector (DBR). Bottom reflector region 103 contains an n-type DBR. Substrate 104 is a conductive n-type substrate. The quantum wells and DBRs are grown on substrate 104 in an epitaxial process. Top reflector region 102 and bottom reflector region 103 each contain a stack of mirror pairs. For example, a mirror pair of top reflector region 102 has a layer 105 and a layer 106. Layer 105 contains Al_{0.7}Ga_{0.3}As, while layer 106 contains GaAs. The term “mirror pair” as used herein indicates two quarter-wavelength layers, where one quarter-wavelength layer is formed over the other quarter-wavelength layer. The term “quarter-wavelength layer” as used herein indicates a layer that has thickness of ((2n−1)/4)λ for the light in the layer, where n is an integer and λ is the wavelength. As such, the optical thickness of a mirror pair is a half wave and each mirror pair functions as a reflector.

FIG. 1 depicts VCSEL 100 at a fabrication stage after an oxidation process. The oxidation is utilized to convert a high Al-content (i.e., aluminum-content) layer into an oxide layer 107 (e.g., AlₓO_{y} layer). The high Al-content layer contains AlAs. As the oxidation rate is strongly dependent on the Al content, the high rate of oxidation of the high Al-content layer creates an oxide aperture 108. As layers 105 also contain Al and are exposed in the oxidation process, oxide layers 109 are formed between epitaxial layers 106. The term “epitaxial layer” as used herein indicates a layer that is grown epitaxially. Due to a slower oxidation rate, oxide layers 109 are located around the edge of the mesa. As certain sections of layers 105 become oxide layers 109, the edges of layers 105 and 106 are mismatched along the vertical direction or Z direction.

When oxide layers 109 are formed and replace certain sections of layers 105, high mechanical stress may be built up, especially in a region around interfaces between layers 105 and 109 and between layers 106 and 109, such as a region 110. The high mechanical stress can create structural weakness and even cause a catastrophic premature random failure of VCSEL 100.

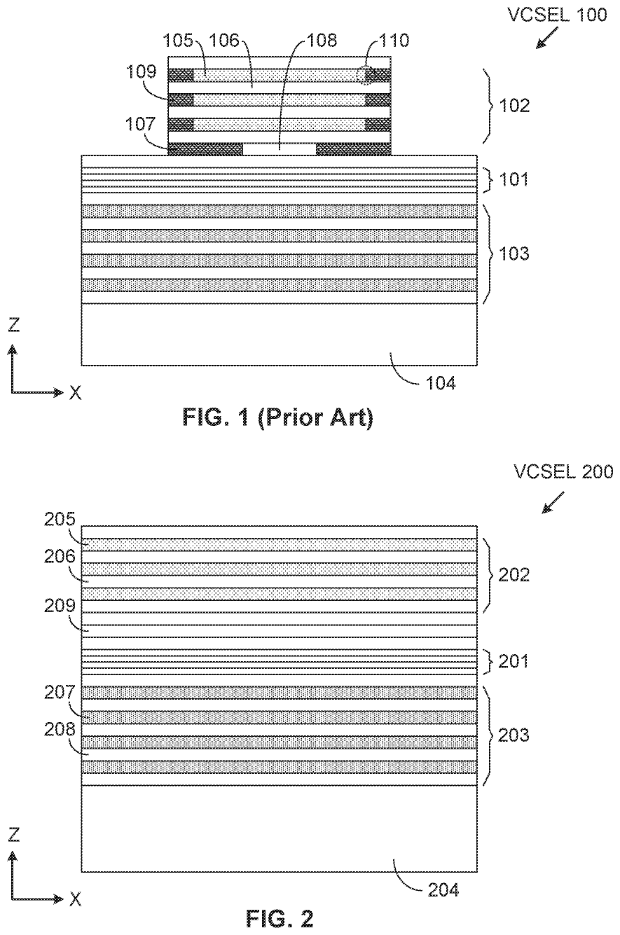

FIG. 2 schematically shows a VCSEL 200 in a cross-sectional view at a certain fabrication stage according to embodiments of the present invention. The cross-sectional view is in an X-Z plane. As shown in FIG. 2, VCSEL 200 may include an active region 201, a top reflector region 202 over active region 201, and a bottom reflector region 203 over a substrate 204. Active region 201 is over bottom reflector region 203 and between top and bottom reflector regions 202 and 203. Active region 201 may contain a MQW configuration in some cases. Top and bottom reflector regions 202 and 203 include a conductive p-type DBR structure and a conductive n-type DBR structure, respectively. Top reflector region 202 has a stack of mirror pairs that includes layers 205 and 206, while bottom reflector region 203 has a stack of mirror pairs that includes layers 207 and 208. In some aspects, a stack of a DBR structure may include more than 20 mirror pairs. A high Al-content layer 209 is between top reflector region 202 and active region 201 optionally. Bottom reflector region 203, active region 201, layer 209, and top reflector region 202 may be grown epitaxially and consecutively over substrate 204 by metal organic chemical vapor deposition (MOCVD) or molecular beam epitaxy (MBE).

In some embodiments, layers 205 and 206 may contain AlₓGa₁₋ₓAs and GaAs, respectively: layers 207 and 208 may contain Al_{y}Ga_{1-y}As and GaAs, respectively; layer 209 may contain Al_{z}Ga_{1-z}As; and substrate 204 may be a GaAs substrate. Exemplary output wavelength of VCSEL 200 may be 850, 980, or 1100 nanometers. Optionally, a dielectric layer (not shown) such as a silicon nitride layer may be deposited as a protective layer over the top of VCSEL 200.

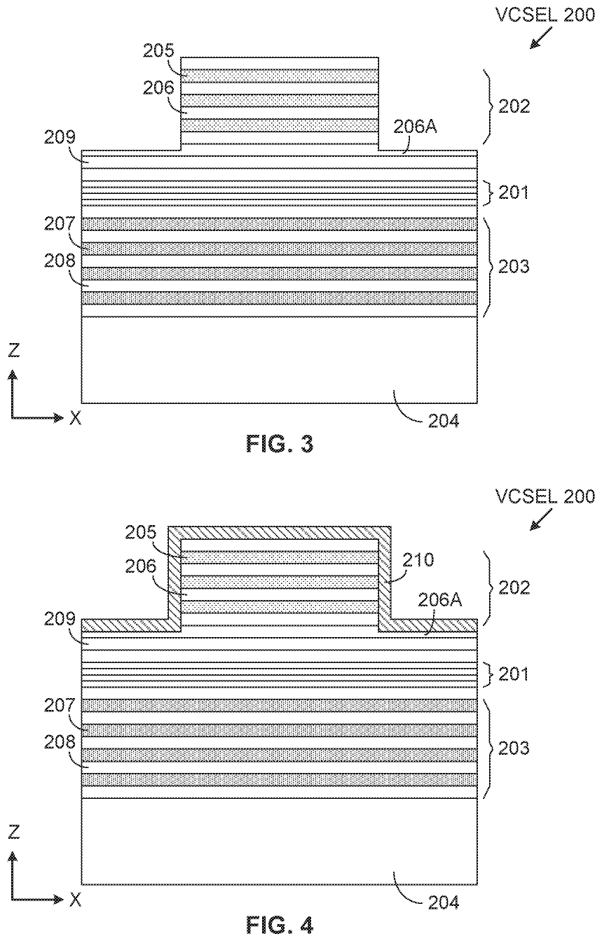

FIG. 3 schematically shows VCSEL 200 in a cross-sectional view after an etch process according to embodiments of the present invention. The etch process may include dry etch or a combination of dry etch and wet etch. A mesa is formed after certain parts of the top reflector region 202 are removed by the etch. In some cases, the mesa has a cylindrical shape and the cross-section of the mesa is a circle in an X-Y plane or horizontal plane. Sides of layers 205 and 206 are exposed on the side of the mesa. Layer 206A is over and adjacent to layer 209, the high Al-content layer. In some aspects, the etch process is arranged such that a part of layer 206A is removed and layer 206A becomes exposed, while layer 209 remains covered by layer 206A. In some other cases, the etch process may be arranged such that layer 206A beside the mesa is removed and layer 209 becomes exposed. In descriptions below, as an example, layer 209 is covered by layer 206A after the etch. Thereafter, a dielectric material (e.g., silicon nitride) is deposited by chemical vapor deposition (CVD) or atomic layer deposition (ALD). A dielectric layer 210 is formed that covers the mesa and exposed part of layer 206A, as shown in FIG. 4.

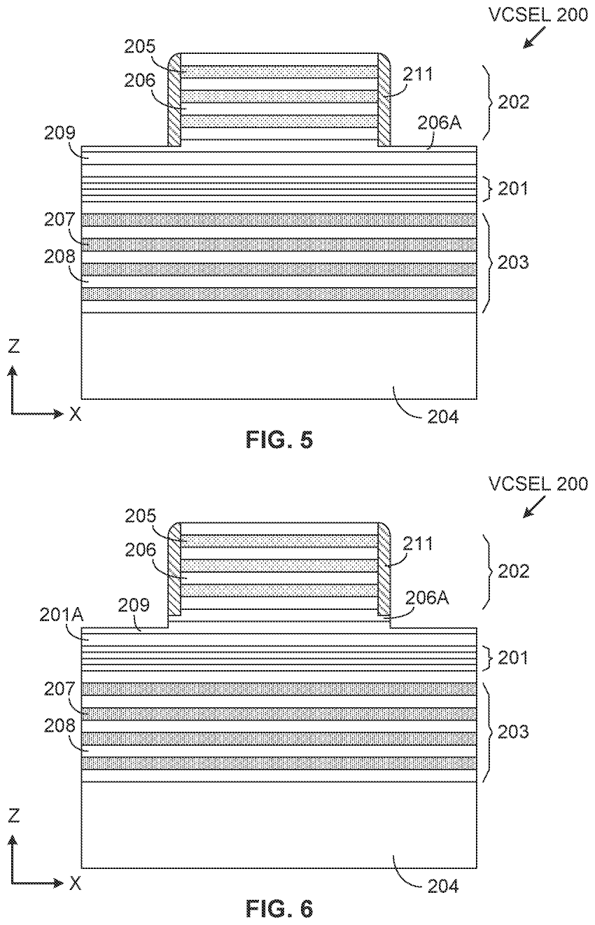

Further, a dry etch is performed to etch away portions of layer 210 to create a dielectric sidewall 211 covering the side of the mesa and layer 206A is exposed again, as shown in FIG. 5. Further, another dry etch is performed to etch out layers 206A and 209 that are beside the mesa. In some cases, layer 209 is partially etched, and a layer 201A that is beneath and adjacent to layer 209 is not exposed after layer 209 is exposed, as shown in FIG. 6. Alternatively, layer 209 may be etched to expose layer 201A beneath it. In following descriptions, layer 201A beneath layer 209 is not exposed exemplarily after the other dry etch.

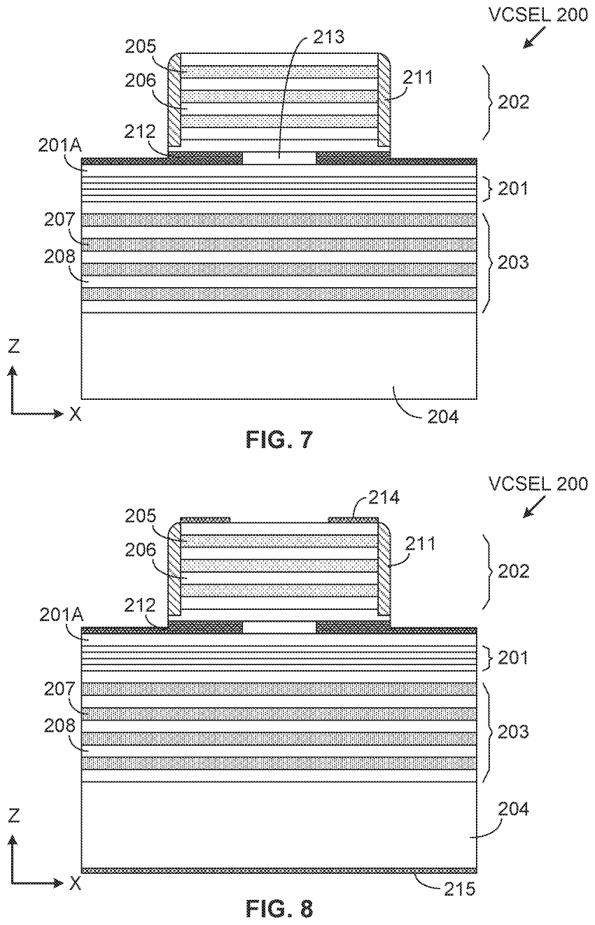

Further, a timed oxidation process is performed in a high temperature (e.g., 400 degrees Celsius) steam environment or a dry oxygen environment. FIG. 7 schematically shows VCSEL 200 in a cross-sectional view after the oxidation process according to embodiments of the present invention. Due to the selective lateral oxidation of layer 209, an oxide layer 212 is generated between epitaxial layers 206A and 201A. Oxide layer 212 may contain, e.g., AlₓO_{y}. When the mesa has a circular cross-section in an X-Y plane, oxide layer 212 may have an annular or ring shape and an oxide aperture 213 is created inside the ring. As such, layer 209 is a layer where oxide layer 212 and oxide aperture 213 are formed from. Because of sidewall 211, layers 205 are not exposed. Hence, Al-containing layers 205, partially oxidized during a conventional oxidation process, are shielded from being oxidized with the existence of sidewall 211. Since layers 205 are not converted into oxide layers, the mechanical stress as mentioned above is not created. Reliability issues associated with the stress and structural weakness may be mitigated.

Layer 209 has relatively high Al content compared to layers 206A and 201A so that oxide aperture 213 may be formed only from layer 209. In some aspects, layers 206A and 201A may have no Al content (e.g., GaAs). In these cases, VCSEL 200 may have one oxide layer (i.e., layer 212) between epitaxial layers. Optionally, layers 206A and/or 201A may have Al content (e.g., Al_{0.5}Ga_{0.5}As) and can be converted into oxide layers. In such cases, VCSEL 200 may have two or three oxide layers (including layer 212) between epitaxial layers. As such, when layers 206A and/or 201A has Al content and is oxidized partially, the oxidation process only produces at most two or three oxide layers between epitaxial layers. Further, the oxide layer or oxide layers (or all oxide layers between epitaxial layers) are closer to active region 201 than the upper portion of top reflector region 202. Assuming top reflector region 202 has twenty mirror pairs, i.e., the quantity of layers 205 is 20. When sides of layers 205 are not covered by a sidewall, twenty more oxide layers may be formed. As sidewall 211 prevents layers 205 from being oxidized, the reliability issues may be improved.

As layers 205 are not oxidized, layers 205 are not altered by the oxidation process. Thus, edges of layers 205 and 206 remain in direct contact with sidewall 211, and are aligned along the Z direction or a direction (or a line) approximately perpendicular to substrate 204, as shown in FIG. 7. On the other hand, if layers 205 are oxidized and become oxide layers partially, the edges of layers 205 move along the X direction (or a radial direction when the mesa is a cylinder) during the oxidation process. In such cases, the edges of layers 205 and 206 are mismatched along the Z direction. Sidewall 211 may be surrounded by air, vacuum, a conductive material such as metal, or a dielectric material deposited there. The air, vacuum, conductive material, or dielectric material and sidewall 211 form a surrounding region that surrounds top reflector region 202. The edges of layers 205 and 206 contact the surrounding region directly.

In some aspects, the Al content of layers 205 and 207 may be lower than that of layer 209. For example, layers 205 and 206 may contain Al_{0.7}Ga_{0.3}As and GaAs, respectively; layers 207 and 208 may contain Al_{0.7}Ga_{0.3}As and GaAs, respectively; and layer 209 may contain AlAs. In these cases, layers 205 are changed into oxide layers partially when sidewall 211 is not deposited. When sidewall 211 is in place, however, layers 205 are not oxidized during the oxidation process.

Further, when sidewall 211 covers the sides of layers 205, at least a part of layers 205 and/or 207 may have the same Al content as that of layer 209 in some cases. For example, layers 205, 207, and 209 may contain AlAs; layers 206A and 201A may contain Al_{0.6}Ga_{0.4}As; and layers 206 and 208 may contain GaAs. In addition, the value of Al content of at least a part of layers 205 and/or 207 may be optionally larger than that of layer 209. For example, layers 205 and 207 may contain AlAs, while layer 209 may contain Al_{0.9}Ga_{0.1}As.

An ALD Al₂O₃ layer or an equivalent layer may be deposited after oxidation over layers 211, 212 and the mesa top, to form an overall (covering everything) moisture-resisting barrier layer for better protection of the structure during subsequent processing steps, and better performance and reliability of the VCSEL in a damp-heat environment. A photoresist pattern definition and subsequent etch step open a window in the ALD Al₂O₃ layer on top of the mesa for subsequent metal contact formation.

FIG. 8 schematically shows VCSEL 200 in a cross-sectional view after a metal deposition process according to embodiments of the present invention, provided VCSEL 200 is a top-emitting VCSEL device. At a certain stage, a metal deposition process is performed to form a metal layer 214 over top reflector region 202. For example, a photoresist layer may be deposited over VCSEL 200. A part of the photoresist layer may be exposed and developed. Other parts of the photoresist layer that are not exposed and developed may be removed. Then, metal layer 214 may be deposited in areas where the photoresist layer is removed in a lift-off process. When the top surface of VCSEL 200 is covered by a protective dielectric layer (e.g., the ALD Al₂O₃ layer), this dielectric layer may be etched away first after the photoresist layer is removed. Metal layer 214 may have a ring shape in some cases, and is the p-metal contact that is electrically connected to top reflector region 202. In some embodiments, metal layer 214 may be made at an earlier stage, for example, before formation of the mesa or the oxidation process. A dielectric layer may be deposited subsequently to cover and protect metal layer 214.

Thereafter, a metal layer 215 may be deposited on the bottom of substrate 204 to form the n-metal contact, as shown in FIG. 8. If VCSEL 200 is a bottom emitting VCSEL device, metal layer 215 may have a ring shape (not shown) to create a window for an output beam.

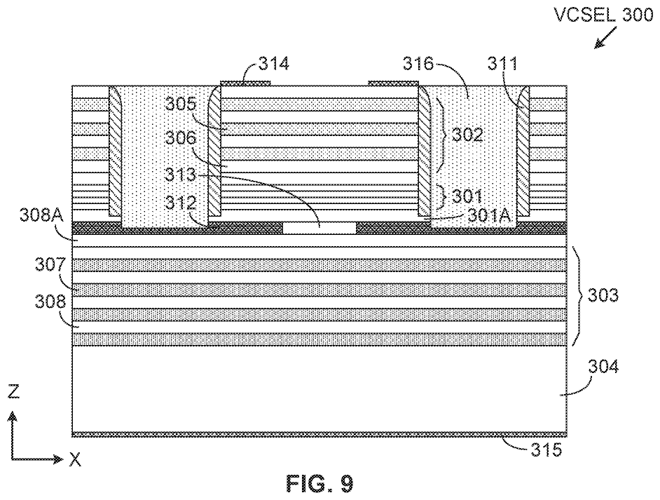

FIG. 9 schematically shows a VCSEL 300 in a cross-sectional view at a stage of a fabrication process according to embodiments of the present invention. The cross-sectional view is in an X-Z plane. VCSEL 300 may include an active region 301, a top reflector region 302, a bottom reflector region 303, and a substrate 304. Active region 301 is between top and bottom reflector regions 302 and 303, and contains a MQW configuration. Top and bottom reflector regions 302 and 303 include a p-type DBR structure and an n-type DBR structure, respectively. Top reflector region 302 includes layers 305 and 306 that form a stack of mirror pairs, while bottom reflector region 303 includes layers 307 and 308 that form another stack of mirror pairs. Optionally, a high Al-content layer is disposed between active region 301 and bottom reflector region 303. Similar to VCSEL 200, layers 305 and 306 may contain AlₓGa₁₋ₓAs and GaAs, respectively; layers 307 and 308 may contain Al_{y}Ga_{1-y}As and GaAs, respectively; the high Al-content layer may contain Al_{z}Ga_{1-z}As; and substrate 304 may be a GaAs substrate.

During the fabrication process, the layers of VCSEL 300 (e.g., layers 305-308 and layers of the MQW) may be grown epitaxially over substrate 304 by MOCVD or MBE. Further, an etch such as a dry etch is performed to form a trench. The trench may have an annular shape in an X-Y plane, creating a cylindrical mesa. Sides of layers 305-306 and active region 301 in the mesa are exposed in the trench. Provided a layer 301A is between the active region 301 and the high Al-content layer. In some aspects, the etch process is arranged such that a part of layer 301A is removed and layer 301A becomes exposed, while the high Al-content layer remains covered by layer 301A. In some other cases, the etch process may be arranged such that layer 301A is removed and the high Al-content layer becomes exposed. In descriptions below, the former scenario applies exemplarily. Further, a dielectric sidewall 311 is formed to cover the exposed sides of layers 305-306 and active region 301.

Thereafter, a dry etch is performed to etch out layer 301A and the high Al-content layer that are beside the mesa and at the bottom of the trench. In some cases, the high Al-content layer is partially etched, and a layer 308A that is beneath and adjacent to the high Al-content layer is not exposed. Alternatively, the high Al-content layer may be etched to expose layer 308A beneath it. In following descriptions, the former scenario applies exemplarily, i.e., layer 308A is not exposed after the dry etch.

Further, a timed oxidation process (e.g., a wet oxidation process) is performed. The high Al-content layer is oxidized to form an oxide layer 312 and oxide aperture 313. Because of sidewall 311, layers 305 are not exposed. Since layers 305 are not converted into oxide layer, the mechanical stress as depicted above is not created by the oxidation process.

The high Al-content layer has relatively high Al content compared to layers 301A and 308A for aforementioned reasons. In some aspects, layers 301A and 308A may contain GaAs and have no Al content. In these cases, VCSEL 300 may have one oxide layer (i.e., layer 312) between epitaxial layers. Optionally, layers 301A and/or 308A may have Al_{0.5}Ga_{0.5}As, and can be converted into an oxide layer. In such cases, VCSEL 300 may have two or three oxide layers (including layer 312) between epitaxial layers, or at most two or three oxide layers (including layer 312) between epitaxial layers.

As layers 305 are not oxidized, layers 305 are changed by the oxidation process. Edges of layers 305 and 306 remain in direct contact with sidewall 311, and edges of layers 305 and 306 and active region 301 are aligned along the Z direction or a line approximately perpendicular to substrate 304, as shown in FIG. 9. Further, a deposition process (e.g., CVD) may be performed to fill the trench with a dielectric material 316 (e.g., silicon oxide, silicon nitride, or polyimide). Optionally, the trench may be filled with a conductive material such as metal. Sidewall 311 and dielectric material 316 (or the conductive material) form a surrounding region surrounding the mesa. The edges of layers 305 and 306 contact the dielectric region directly. Provided VCSEL 300 is a top-emitting device. An annular metal layer 314 as the p-metal contact is grown over top reflector region 302, and a metal layer 315 as the n-metal contact is grown on the bottom of substrate 304. If VCSEL 300 is configured for bottom emission, metal layer 315 may have an annular shape (not shown) to form an output window.

Because of sidewall 311, the value of Al content of at least a part of layers 305 may be the same as or even larger than that of the high Al-content layer in some cases. For example, layers 305 and 307 may contain AlAs; the high Al-content layer may contain AlAs or Al_{0.9}Ga_{0.1}As: layers 301A and 308A may contain Al_{0.6}Ga_{0.4}As or GaAs; and layers 306 and 308 may contain GaAs.

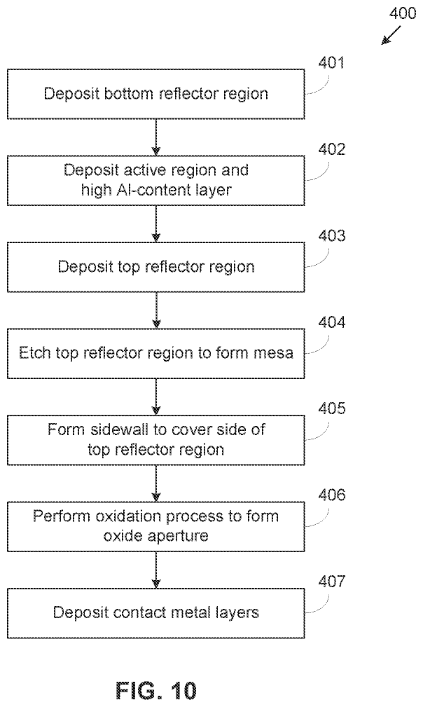

FIG. 10 is a flow chart illustrating a schematic fabrication process 400 for a VCSEL, according to embodiments of the present invention. Process 400 starts from providing a substrate such as an n-type GaAs wafer. At step 401, multiple layers as a bottom reflector region are grown epitaxially over the substrate. The bottom reflector region includes a stack of mirror pairs as a DBR structure. At step 402, an active region is grown epitaxially. The active region may include a MQW region. Further, a high Al-content layer is deposited epitaxially. Alternatively, the high Al-content layer may also be deposited between steps 401 and 402. At step 403, multiple layers as a top reflector region are grown epitaxially. The top reflector region includes a stack of mirror pairs as another DBR structure.

At step 404, a mesa structure is formed by etching away a part of the top reflector region. In some cases, a trench is formed by the etch. The trench encircles the mesa structure horizontally and extends through the top reflector region along a vertical direction. The trench exposes the side of the top reflector region. A layer above the high Al-content layer is also exposed at the bottom of the trench.

At step 405, a dielectric sidewall is fabricated to cover the exposed side of the top reflector region, i.e., sides of the mirror pairs above the active region. Further, an etch is conducted to make the trench deeper to expose the high Al-content layer.

At step 406, an oxidizing process (e.g., using hot water vapor) is implemented to oxidize the high Al-content layer to form an oxide layer and an oxide aperture. The trench is then filled with one or more dielectric materials to form an isolation region. At step 407, a top contact metal layer and a bottom contact metal layer are deposited, respectively.

During the oxidizing process, layers containing Al at the top reflector region are not oxidized because the dielectric sidewall blocks the oxygen. As such, oxide layers are not formed there and corresponding high mechanical stress and structural weakness are not generated. The methods illustrated above may be used to improve the reliability of VCSELs and VCSEL arrays.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments. Furthermore, it is intended that the appended claims cover any and all such applications, modifications, and embodiments within the scope of the present invention.

We claim:

1. A Vertical Cavity Surface Emitting Laser (VCSEL) device, comprising:
a substrate;
a first reflector region over the substrate;
a second reflector region over the first reflector region;
an active region between the first reflector region and second reflector region; and
an oxide aperture proximate to the active region, wherein the second reflector region comprises a plurality of mirror pairs, the mirror pair comprises a first layer and a second layer, and an edge of the first layer and an edge of the second layer are aligned along a direction approximately perpendicular to the substrate.

2. The VCSEL device of claim 1, wherein the plurality of mirror pairs form a distributed Bragg reflector (DBR) structure.

3. The VCSEL device of claim 1, wherein the active region includes a multiple-quantum-well (MQW) configuration.

4. The VCSEL device of claim 1, wherein the second reflector region is surrounded by a surrounding region and the edge of the first layer and the edge of the second layer contact the surrounding region.

5. The VCSEL device of claim 1, wherein all oxide layers between epitaxial layers are closer to the active region than an upper portion of the second reflector region.

6. The VCSEL device of claim 1 further comprising less than ten oxide layers between epitaxial layers.

7. The VCSEL device of claim 1, wherein a value of aluminum content of one of the first layer and second layer is same as or larger than a value of aluminum content of a layer from which the oxide aperture is formed.

8. A method for fabricating a Vertical Cavity Surface Emitting Laser (VCSEL) device, comprising:
growing a first reflector region over a substrate;
growing an active region over the first reflector region;
growing a second reflector region over the active region, the second reflector region comprising a mirror pair including a first layer and a second layer;
removing a portion of the second reflector region by etch, sides of the first layer and the second layer exposed after the portion is removed;
forming a dielectric layer over the exposed sides of the first and second layers; and
performing an oxidation process to form an oxide aperture for the VCSEL device.

9. The method of claim 8 further comprising exposing a layer including aluminum content before performing the oxidation process.

10. The method of claim 8, wherein the first reflector region and the second reflector region each comprise a distributed Bragg reflector (DBR) structure.

11. The method of claim 8, wherein the active region includes a multiple-quantum-well (MQW) configuration.

12. The method of claim 8, wherein an edge of the first layer and an edge of the second layer are aligned along a direction approximately perpendicular to the substrate after the oxidation process is performed.

13. The method of claim 8, wherein an edge of the first layer and an edge of the second layer contact the dielectric layer.

14. The method of claim 8, wherein all oxide layers between epitaxial layers are closer to the active region than an upper portion of the second reflector region.

15. A Vertical Cavity Surface Emitting Laser (VCSEL) device, comprising:
a substrate;
a first reflector region over the substrate;
a second reflector region over the first reflector region and surrounded by a dielectric region;
an active region between the first reflector region and second reflector region; and
an oxide aperture proximate to the active region, wherein the second reflector region comprises a plurality of mirror pairs, the mirror pair comprises a first layer and a second layer, and an edge of the first layer and an edge of the second layer contact the dielectric region.

16. The VCSEL device of claim 15, wherein the plurality of mirror pairs form a distributed Bragg reflector (DBR) structure.

17. The VCSEL device of claim 15, wherein the active region includes a multiple-quantum-well (MQW) configuration.

18. The VCSEL device of claim 15, wherein the edge of the first layer and the edge of the second layer are aligned along a direction approximately perpendicular to the substrate.

19. The VCSEL device of claim 15, wherein all oxide layers between epitaxial layers are closer to the active region than an upper portion of the second reflector region.

20. The VCSEL device of claim 15 further comprising less than ten oxide layers between epitaxial layers.
